(19) United States
(12) Patent Application Publication
(10) Pub. No.: US 2011/0159446 A1
(43) Pub. Date: Jun. 30, 2011

(54) PLASMON HEAD WITH HYDROSTATIC GAS BEARING FOR NEAR FIELD PHOTOLITHOGRAPHY

(75) Inventor: Zine-Eddine Boutaghou, North Oaks, MN (US)

(73) Assignee: First Principles Technology, LLC

(21) Appl. No.: 12/766,542

(22) Filed: Apr. 23, 2010

Related U.S. Application Data
(60) Provisional application No. 61/172,685, filed on Apr. 24, 2009.

(51) Int. Cl. G03F 7/20; G03B 27/42; G11B 11/03

(52) U.S. Cl. 430/325; 355/53; 369/13.33

(57) ABSTRACT

A low-cost approach to near field nano-scale photolithography using a plasmonic head with hydrostatic gas bearings. The hydrostatic gas bearing flies the plasmonic head at less than 100 nm, and more preferably less than 50 nm, above the photo-resist without the need to spin the substrate. The plasmonic head concentrates short-wavelength surface plasmons into about sub-100 nm regions on the photo-resist and can pattern features of about 80 nm or less.

### RELATED APPLICATIONS

The present application claims the benefit of U.S. Provisional Patent Application Ser. No. 61/172,685 entitled Plasmon Head with Hydrostatic Gas Bearing for Near Field Photolithography, filed Apr. 24, 2009.

### FIELD OF THE INVENTION

This invention relates to plasmonic heads with hydrostatic gas bearings for near field nano-scale photolithography.

### BACKGROUND OF THE INVENTION

The continuing size reduction of integrated circuits to nanometer (nm) scale dimensions requires the development of new lithographic techniques. The ultimate resolution of conventional photolithography is restricted by the diffraction limit. It is becoming increasingly difficult and complex to use the established method of optical projection lithography at the short optical wavelengths required to reach the desired feature sizes. For example, the use of wavelengths in the deep ultraviolet, the extreme ultraviolet (EUV), or the X-ray regime requires increasingly difficult adjustments of the lithographic process, including the development of new light sources, photo-resists, and optics.

U.S. Pat. Publication No. 2003/0129545 (Kik et al.) discloses a method for performing nanolithography using a photo-mask with conductive nanostructures disposed thereon. The nanostructures have a plasmon resonance frequency that is determined by the dielectric properties of the surroundings and of the nanostructures, as well as the nanostructure shape. The nanostructures are illuminated with light at or near the frequency of the plasmon resonance frequency, which causes collective oscillations of the electrons at the surface of the nanostructure. These oscillations can have wavelengths that are much shorter than the wavelength of the light that excited them, which are sufficient to modify adjacent portions of the resist layer. The resist layer is developed to create plasmon printed, subwavelength patterns. Creating the photo-mask, however, is time intensive, expensive, and does not easily permit design changes.

The commercialization of nanoscale devices requires the development of high-throughput nanofabrication technologies that allow frequent design changes. Maskless nanolithography, including electron-beam and scanning-probe lithography, offers the desired flexibility, but is limited by low throughput and extremely high cost.

U.S. Pat. Publication No. 2007/0069429 (Albrecht et al.) is directed to a system and method for patterning a master disk to be used for nanoimprinting magnetic recording disks. An air-bearing created by a rotating master disk substrate supports a slider with an aperture structure within the optical near-field of a resist layer. The fly height of the slider is typically about 10 to about 20 nanometers. A liquid lubricant and/or a protective film, such as a carbon film, may be provided on the resist layer to improve the flyability of the slider supporting the plasmonic head. The timing of the laser pulses is controlled to form a pattern of exposed regions in the resist layer, with this pattern ultimately resulting in the desired pattern of data islands and non-data islands in a magnetic recording disks when they are nanoimprinted by the master disk.

The spinning master disk of Albrecht is essential to establish the air bearing between the slider and the photo-resist. The spinning master disk, however, is subject to vibration and spindle run-out errors that lead to patterning errors and potential collisions between the slider and the photo-resist. Roughness of the photo-resist and media needs to be closely controlled to enable the slider to fly without crashing. If the plasmonic lens contacts the master disk it can be coated with photo-resist, potentially smearing the lens and causing patterning errors. Finally, a spinning master disk is not a practical method of making more complex structures, such as for example micro electrical mechanical systems (MEMS).

### BRIEF SUMMARY OF THE INVENTION

The present invention is directed to a low-cost approach to near field nano-scale photolithography using a plasmonic head with hydrostatic gas bearings. The hydrostatic gas bearing flies the plasmonic head at less than 100 nm, and more preferably less than 50 nm, above the photo-resist without the need to spin the substrate. The plasmonic head concentrates short-wavelength surface plasmons into about sub-100 nm regions on the photo-resist and can pattern features of about 80 nm or less. This nanofabrication system has the potential to provide desktop, maskless nanophotolithography at several orders of magnitude lower cost than current maskless techniques. Nano-scale typically refers to features with dimensions of less than one micrometer (1×10⁶ meters).

At least one plasmonic head is preferably located at the trailing edge of the slider. Alternatively, one or more lenses are mounted on the slider. For commercial applications, a plurality of plasmonic heads are provided on each slider.

The slider is supported by a suspension assembly fabricated with air channels connected to an external air supply. The channels are fluidly coupled to openings in the air bearing surface of the slider. In one embodiment, channels are etched in the suspension assembly and a polyamide cover is applied over the channels to form gas conduits. The channels can be on the top or the bottom of the suspension assembly.

The hydrostatic gas bearing provides a controlled clearance between the substrate and the slider. The clearance is maintained by externally pressurizing a plurality of pads located on the air bearing surface of the slider in proximity with the substrate. Once the desired clearance is attained between the hydrostatic slider and the substrate, a laser is directed at a near field transducer located on the slider. The resulting emission from the near field transducer exposes the photo-resist.

In one embodiment, the externally pressurized gas bearing design allows for independently controlling the pressure on each pad of the hydrostatic bearing. Independent control of each gas port permits the pitch and roll of the slider to be adjusted to optimize the photolithographic process.

The clearance of the slider is preferably calibrated ex-situ on an optical fly height tester prior to usage. Each hydro-static pad pressure is calibrated to assure a near field gap. A sensor is preferably provided on the slider to monitor flying height. Heaters may also be provided adjust the position of the plasmonic head relative to the photo-resist.

The system includes an X-Y stage to accurately locate a substrate relative to the slider. A controller operating the X-Y stage and the laser assembly accurately expose the photo-resist to form the desired pattern. Since the substrate is not required to spin to maintain a gas bearing, transfer of vibration and spindle run-out errors to the pattern are minimized.

Micro electro mechanical systems (MEMS) methods are well suited for fabricating the present hydrostatic slider. For example, a silicon wafer is patterned with the gas bearing features. A series of through holes for the gas ports are machined with a deep reactive ion etch process (DRIE) or simply machined. Once the silicon wafers are patterned and fabricated, a series of slider bars are sliced to expose the slider sides for further processing. A thick dielectric such as alumina is sputtered at the end of slider. A planar solid immersion mirror with a dual offset grating used to focus a waveguide mode onto the near-field transducer (NFT) is fabricated onto the trailing edge of the slider.

The photolithography system includes a head suspension assembly with a load beam having a flexure at a distal end and a plurality of channels. A covering layer extends over the channels to form gas conduits. The slider includes a first surface attached to the flexure and a second surface facing the substrate. The first surface of the slider includes a plurality of ports fluidly coupled to the gas conduits. The ports extend through the slider and exit through holes in at least one air bearing surface located on the second surface. A near field assembly on the slider emits radiation onto a region of the photo-resist in response to incident radiation. The region has a maximum dimension of less than about 100 nanometers. A laser assembly supplies the incident radiation. A source of pressurized gas delivered to the gas conduits maintains a clearance between the near field assembly and the photo-resist layer of less than about 100 nanometers. A controller synchronizes activation of the laser assembly with the position of the substrate relative to the near field assembly to form the desired pattern on the photo-resist layer.

The substrate can be one or more of flexible, rigid, planar, non-planar, or cylindrical. The laser assembly supplies radiation at a first wavelength and the near field assembly emits radiation at a second shorter wavelength in response to incident radiation. The region of radiation emitted onto the photo-resist has a maximum dimension of less than about 80 nanometers, and preferably a maximum dimension of less than about 60 nanometers.

The pattern has features with sizes less than about a wavelength of the incident radiation. The features are preferably less than about 50% of a wavelength of the incident radiation, and more preferably less than about 20%.

The slider preferably includes a sensor monitoring the clearance between the near field assembly and the photo-resist layer. The clearance between the near field assembly and the photo-resist layer of less than about 50 nanometers, and more preferably less than about 20 nanometers.

The present invention is also directed to a plasmonic head for near field photolithography.

The present invention is also directed to a method for forming a pattern in photo-resist layer on a substrate using a photolithography system. A pressurized gas is delivered through conduits in a head suspension to ports on a slider. The pressurized gas is ejected from the ports in the slider to create a hydrostatic gas bearing with a clearance between a near field assembly and a photo-resist layer of less than about 100 nanometers. Incident radiation is directed from a laser assembly to the near field assembly. A region of radiation with a maximum dimension of less than about 100 nanometers is emitted from the near field assembly onto the photo-resist in response to the incident radiation. Activation of the laser assembly is synchronized with a position the substrate relative to the near field assembly to form the pattern.

### BRIEF DESCRIPTION OF THE SEVERAL VIEWS OF THE DRAWING

FIG. 1 is a schematic illustration of a maskless, nano-photolithography system with a hydrostatic gas bearing in accordance with an embodiment of the present invention.

FIG. 2A illustrates a near field assembly formed on an edge of a slider in accordance with an embodiment of the present invention.

FIG. 2B is a perspective view of the slider of FIG. 2A.

FIG. 2C is a schematic illustrate of an alternate near field transducer in accordance with an embodiment of the present invention.

FIG. 3 is an exploded view of a head suspension in accordance with an embodiment of the present invention.

FIG. 4 is a top view of the head suspension of FIG. 3.

FIG. 5 is a bottom exploded view of the head suspension of FIG. 3.

FIG. 6 is a perspective view of an alternate head suspension in accordance with an embodiment of the present invention.

FIG. 7 is a bottom view of the slider of FIG. 6.

FIG. 8 is a schematic illustration of a maskless nanophotolithography system with a hydrostatic gas bearing for use with a non-planar substrate in accordance with an embodiment of the present invention.

FIG. 9 is a schematic illustration of a maskless nanophotolithography system with a hydrostatic gas bearing for use with a flexible substrate in accordance with an embodiment of the present invention.

### DETAILED DESCRIPTION OF THE INVENTION

The entire content of U.S. Provisional Patent Application Ser. No. 61/172,685, filed Apr. 24, 2009, is hereby incorporated by reference.

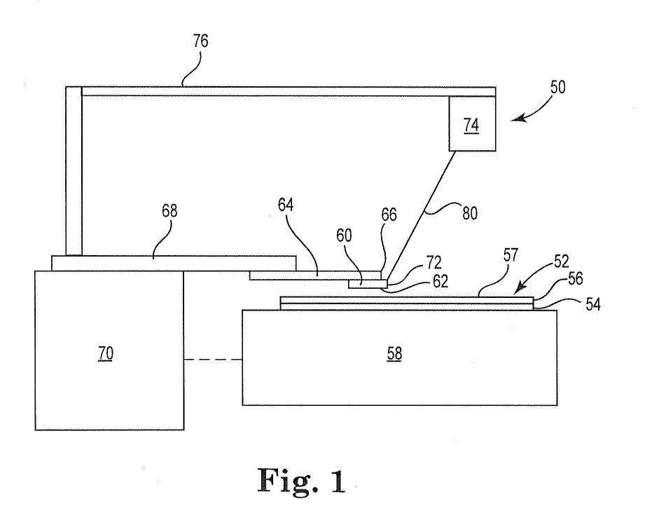

FIG. 1 is a schematic illustration of the system 50 for maskless, nano-scale, photolithography in accordance with an embodiment of the present invention. A master 52 including a substrate 54 with photo-resist layer 56 supported on X-Y stage 58. Slider 60 has an air-bearing surface (ABS) 62 that is oriented toward the master 52.

The slider 60 is mounted on a suspension 64 similar to a conventional suspension like that used in magnetic recording disk drives, with a head gimbal assembly or flexure 66 that permits the slider 60 to “pitch” and “roll” relative to the master 52. The suspension 64 is connected to support arm 68 that is supported by controller 70. The support aim 68 applies a preload to the suspension 64 to maintain the flying ability of the slider 60.

In one embodiment, the support arm 68 is fixedly mounted on controller 70. In another embodiment, the support arm 68 is adapted to translate relative to the controller 70. Translation can include linear movement in the X, Y, and/or Z directions, as well as rotation around a fixed point. For example, a linear actuator can move the support arm 68 in the X-direction and/or Y-direction. Alternatively, a rotary actuator, such as a rotary voice-coil-motor (VCM) actuator, rotates the support arm 68 along a generally radial or arcuate path.

The slider 60 includes a near field assembly 72 that directs radiation from laser assembly 74 to the resist layer 56. The laser assembly 74 typically includes a laser, a modulator and one or more lenses. Alternatively, one or more lenses may be located on the slider 60. The laser assembly 74 is supported by armature 76 attached to the controller 70. In embodiments where the support arm 68 is permitted to translate relative to the controller 70, the armature 76 preferably translates with the support arm 68 so that the position of the laser assembly 74 relative to the near field assembly 72 is maintained. The master 52 is movable relative to the slider 60 by X-Y stage 58.

Radiation 80 from the laser assembly 74 may be directed to the near field assembly 72 using a variety of techniques, such as for example the system disclosed in U.S. Pat. No. 5,497,359 or U.S. Pat. Publication 2007/0069429, which are hereby incorporated by reference. Alternatively, the radiation 80 from laser assembly 74 may be delivered to the near field assembly 72 by optical fibers.

Most commonly used lasers are diode-pumped solid state lasers, e.g., Nd:YAG or Nd:YLF. These may be frequency multiplexed to give radiation at higher harmonics. For example a Nd:YAG laser with frequency multiplexing may be used to generate radiation at 1064 nm, 532 nm, 355 nm or 266 nm. Additionally, the radiation from the laser may be modulated using external modulators. Mode-locked lasers also provide rapid pulses with frequencies up to about 100 MHz. Other lasers such as pulsed diode lasers may also be used.

The controller 70 can be a specialty computer, a conventional PC, or a combination thereof. The controller 70 is programmed with the desired pattern to be created in the photo-resist 56. The control system 70 controls the X-Y stage 58 and activation of the laser assembly 74 to form the desired pattern in the resist layer 56 of master 52. In another embodiment, the laser assembly 74 delivers pulses on demand, in response to a trigger signal.

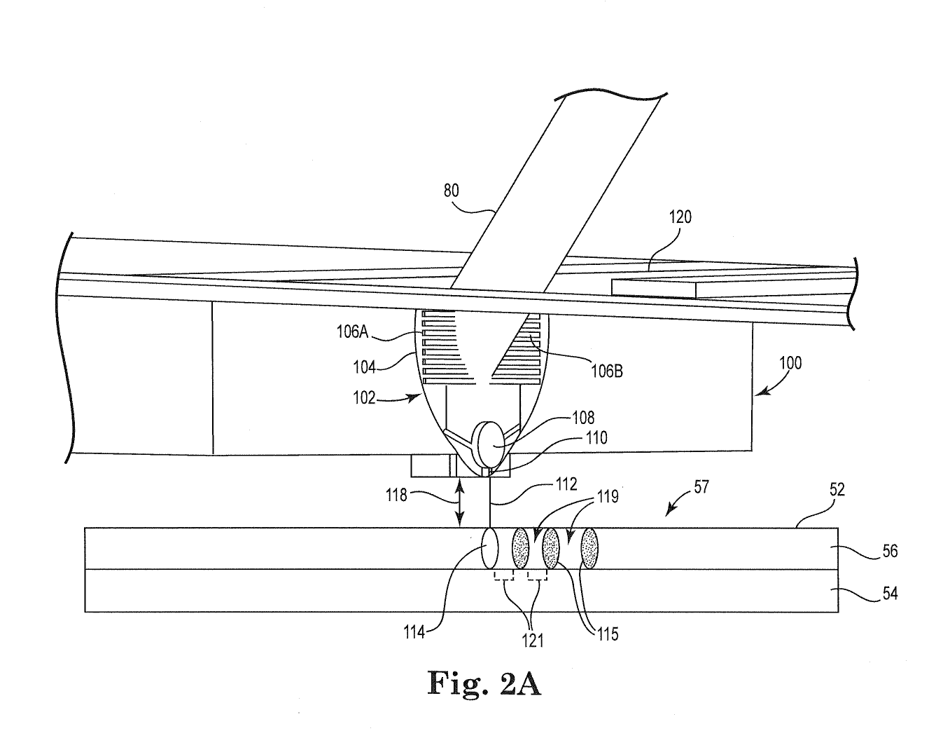

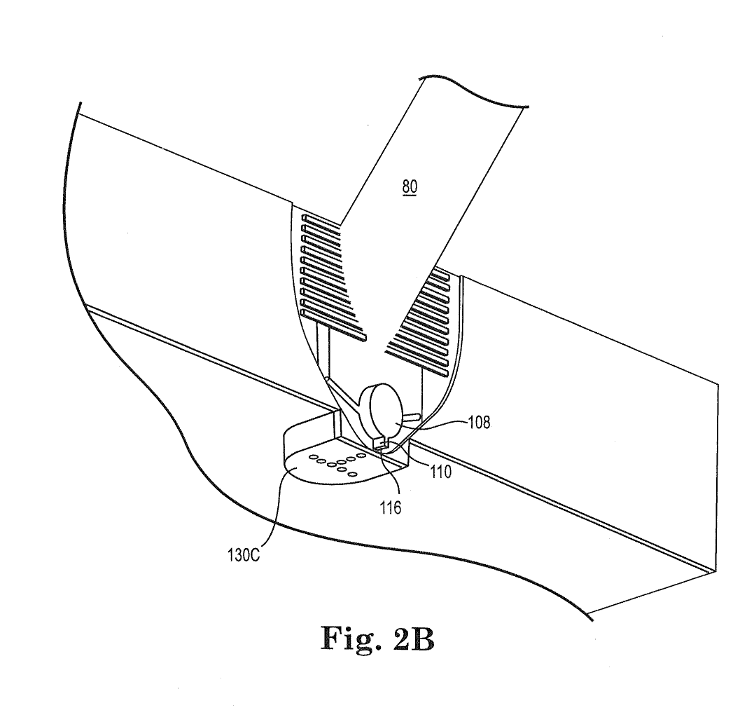

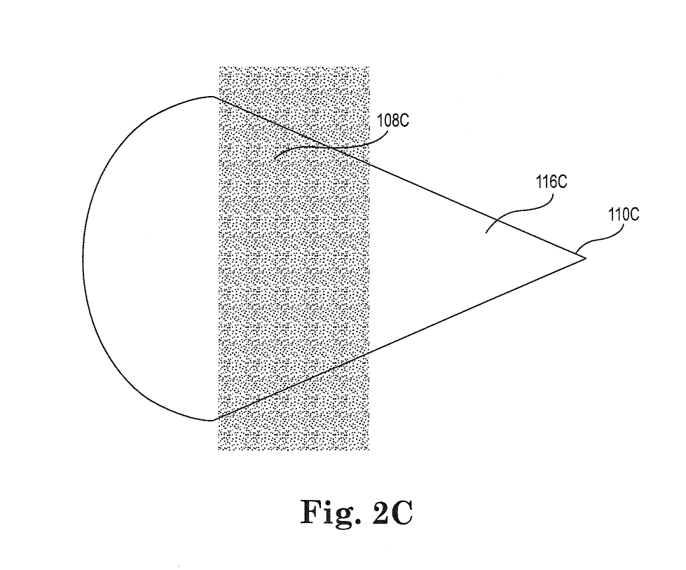

FIG. 2A is an enlarged view of a near field assembly 102 located on a side surface of a slider 100 in accordance with one embodiment of the present invention. Planar solid immersion mirror 104 with dual offset gratings 106A, 106B focuses radiation 80 onto near field transducer 108. The dual offset grating 106A, 106B are offset by half a wavelength of the radiation 80 causing a phase shift. The near field transducer 108 is located at the focus of the planar solid immersion mirror 104. When the near field transducer 108 is excited to surface plasmon resonance, tip 110 couples the light into the photo-resist 56. The tip 110 provides a lightning rod effect for field confinement. A near field assembly suitable for use in the present embodiment is disclosed in Challener, et al. Heat-assisted Magnetic Recording by a Near-field Transducer with Efficient Optical Energy Transfer, DOI: 10.1038 Nature Photonics (2009) and U.S. Pat. No. 7,272,079 (Challener), which are incorporated by reference.

Surface plasmons (SPs) are collective oscillations of surface charge that are confined to an interface between a dielectric and a metal. When surface plasmons are resonantly excited by the external optical field 80, the field amplitude of the output radiation 112 in the vicinity of the region 114 may be orders of magnitude greater than that of the incident radiation 80.

The region 114 of output radiation 112 is tightly confined, with a cross-sectional area much smaller than the incident wavelength 80. The region 114 is typically circular or oval in shape, although a variety of other shapes are possible. The region 114 preferably covers an area with a major dimension of less than about 100 nanometers, and more preferably less than about 80 nanometers, and more preferably less than about 60 nanometers.

The output radiation 112 from the near field transducer 108 heats the photo-mask 56 to form exposed regions 115 with different properties than the unexposed regions 119 of the photo-mask 56. The exposed regions 115 are depicted as corresponding to the size of the region 114 created from a single laser pulse. The size of the exposed regions 115, however, can be modified by varying the on-time of the laser, clearance 118, and a variety of other factors.

After exposure to heat from the output radiation 112, the photo-resist 56 forms a new material different from the unexposed regions. By controlling the position of the master 52 and the pulses from the laser assembly 74, the controller 70 can generate a predetermined pattern. The master 52 is then etched, such as by chemical etchants or reactive-ion-etching (RIE). The exposed regions 115 are resistant to the etching acting as a mask. The exposed regions 115 are resistant to hydrochloric acid mixtures (HCl:H.sub.2O.sub.2:H.sub.2O, 1:1:48) and nitric acid mixtures, while the unexposed regions 119 are removed in the same acid mixture.

The etching is performed into the substrate 54 so that after removal of the remaining photo-resist 56, the substrate 54 has the desired pattern features 121. The present system permits features 121 with dimensions less than the wavelength of the incident radiation 80. The features 121 preferably have a size less than about 50%, more preferably less than about 30%, and most preferably less than about 20%, of the wavelength of the incident radiation. The features 121 preferably have a maximum dimension of less than about 80 nanometers, and more preferably less than about 60 nanometers, and more preferably less than about 40 nanometers.

Due to the exponential decay of the evanescent field of surface plasmons, the tightly focused region 114 only exists at the near field of the near field transducer 108, normally less than about 100 nanometers. To achieve high-speed scanning, clearance 118 between distal end 116 of the tip 110 and surface 57 of the photo-resist 56 is preferably less than about 50 nanometers, and more preferably less than about 20 nanometers to about 10 nanometers, above the photo-resist layer 56.

As best illustrated in FIG. 2B, distal end 116 of the tip 110 is flush with air bearing surface 130C so that the clearance 118 is controlled by the gas bearing. In another embodiment, the tip 110 extends beyond the air bearing surface 130C toward the master 52. This embodiment permits the plasmon field to be closer to the photo-mask 56, while maintaining a greater clearance between the slider 60 and the surface 57 of the photo-resist 56.

FIG. 2C is a schematic illustrate of an alternate near field transducer 108C in accordance with an embodiment of the present invention. Distal end 116C includes pointed tip 110C. The tip 110C concentrates energy from the transducer 108C. A variety of other shapes are possible for the tip 110C, depending on the shape and size of the desired exposed regions 115 (see FIG. 2A).

In some embodiments, the slider 100 may contain one or more heaters to control the position of the near field assembly 102 and/or the near field transducer 108 relative to the surface 57 of the photo-resist layer 56. Various heater configurations and methods for controlling the position of the near field assembly 102 are disclosed in U.S. Pat. No. 5,991,113 (Meyer et al.); U.S. Pat. No. 7,428,124 (Song et al.); U.S. Pat. No. 7,430,098 (Song, et al.); and U.S. Pat. No. 7,388,726 (McKenzie et al.); U.S. Publication Nos. 2006/0285248 (Pust et al.) and 2007/0035881 (Burbank et al.); and U.S. application Ser. No. 12/424,441 (Boutaghou et al.), all of which are hereby incorporated by reference.

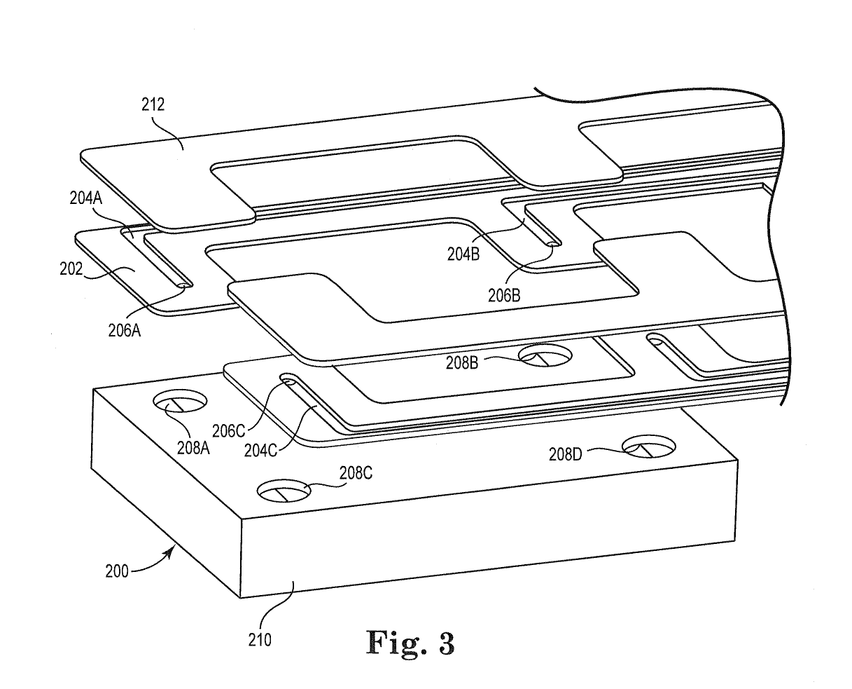

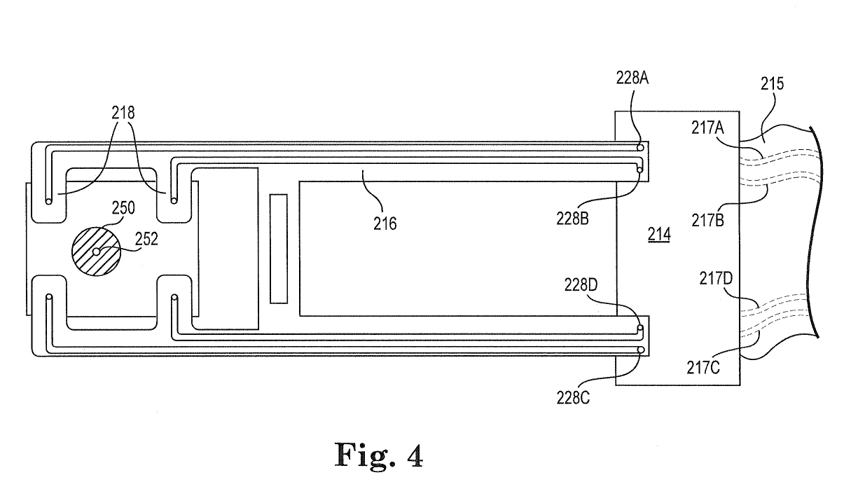

FIGS. 3 through 5 illustrate a suspension assembly 200 capable of generating a hydrostatic gas bearing in accordance with an embodiment of the present invention. Stainless steel suspension 202 is etched to create channels 204A, 204B, 204C, 204D (collectively “204”). In the illustrated embodiment, distal ends of the channels 204 terminate in through holes 206A, 206B, 206C, 206D (collectively “206”). The through holes 206 are configured to align with ports 208A, 208B, 208C, 208D (collectively “208”) in slider 210.

While the illustrated embodiment includes four channels and four ports 208 in the slider 210, a variety of other configurations are possible. In one embodiment, the channels 204A and 204B are combined into a single channel, as are 204C and 204D. As will be discussed herein, the number and/or the locations of ports 208 can also vary. In another embodiment, the channels 204 may be formed in the bottom surface of the suspension 202, making the holes 206 unnecessary.

Sealing layer 212 is located over the top of the channels 204 to form a substantially air-tight seal. In one embodiment, the sealing layer 212 is a polyamide sheet with a pressure sensitive adhesive on one surface. Pressurized gas can be delivered to the channels 204 from base plate 214 attached to load beam 216. In one embodiment, a multi-layered polyamide sheet 215 delivers pressurized gas from the controller 70 to the base plate 214. The polyamide sheet 215 includes conduits 217A, 217B, 217C, 217D (collectively “217”) fluidly coupled to through holes 228A, 228B, 228C, 228D in the base plate 214 and the load beam 216. The pressurized gas travels down the respective channels 204 to flexure 218, out through holes 206, and into the ports 208 on the slider 210.

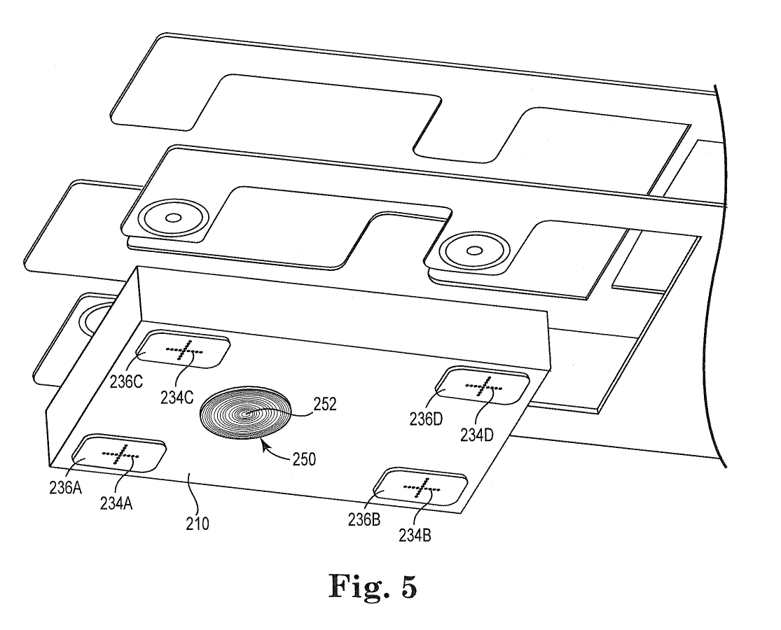

As best illustrated in FIG. 5, bottom surface 230 of the flexure 218 includes recesses 232 around the through holes 206. These recesses 232 mate with the ports 208 on the top of the slider 210. Each port 208 is fluidly coupled to a respective plurality of holes 234A, 234B, 234C, 234D (collectively “234”) formed in respective air bearing surfaces 236A, 236B, 236C, 236D (collectively “236”) on the base of the slider 210. The pressurized gas exits these holes 234 to form a gas bearing between the slider 210 and the master 52.

The controller 70 monitors gas pressure delivered to the slider 60. Gas pressure to each of the four channels 204 is preferably independently controlled so that the pitch and roll of the slider 60 can be adjusted. In another embodiment, the same gas pressure is delivered to each of the channels 204. While clean air is the preferred gas, other gases such as for example argon may also be used. The gas pressure is typically in the range of about 2 atmospheres to about 4 atmospheres.

The slider 210 includes an alternate near field assembly 250 in accordance with another embodiment of the present invention. The near field assembly 250 includes aperture 252 formed of a material, such as glass, quartz or another dielectric material, that is transmissive to radiation 80 at the wavelength of the laser assembly 74. A film 254 of material substantially reflective to the radiation 80 at the wavelength of the laser assembly 74 is located on the disk-facing side 256 around the aperture 252. The aperture 252 is preferably subwavelength-sized, i.e., its diameter if it is circularly-shaped or its smallest feature if it is non-circular, is less than the wavelength of the incident laser radiation 80 and preferably less than one-half the wavelength of the laser radiation 80. A suitable near field assembly 250 is disclosed in U.S. Pat. Publication No. US 2007/0069429.

Optical transmission through a subwavelength aperture in a metal film is enhanced when the incident radiation is resonant with surface plasmons at a corrugated metal surface 250 surrounding the aperture 252. Thus features such as ridges or trenches in the metal film 250 serve as a resonant structure to further increase the emitted radiation output from the aperture 252 beyond what it would be in the absence of these features. The effect is a frequency-specific resonant enhancement of the radiation emitted from the aperture 252, which is then directed onto the photo-resist 56 positioned within the near-field. This resonant enhancement is described by Thio et al., Enhanced Light Transmission Through A Single Subwavelength Aperture, Optics Letters, Vol. 26, Issue 24, pp. 1972-1974 (2001) and in US 2003/0123335.

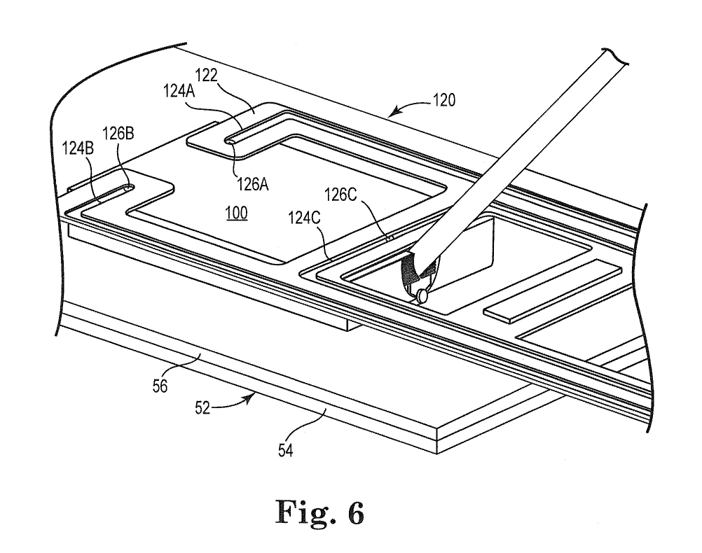

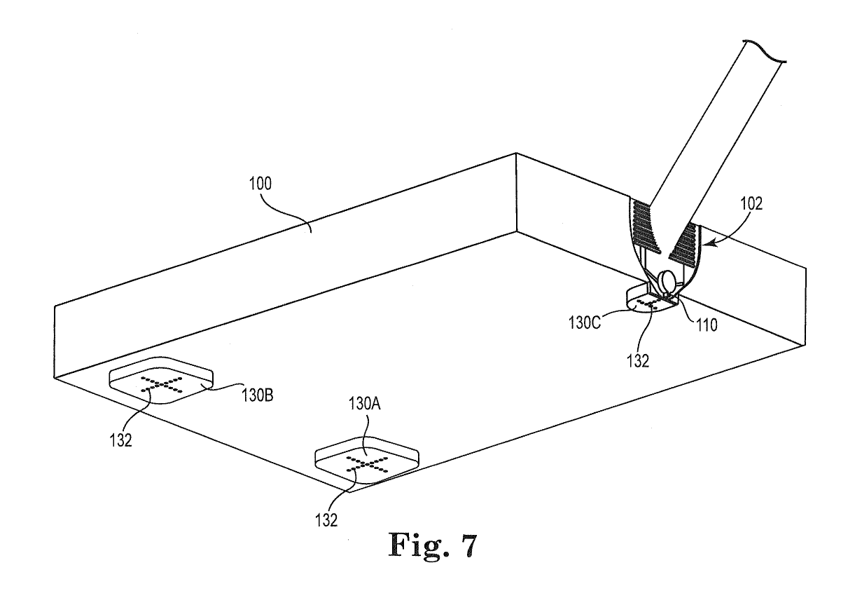

FIGS. 6 and 7 illustrate the slider 100 of FIGS. 2A and 2B as part of a suspension assembly 120 in accordance with an embodiment of the present invention. Top surface 122 of the suspension 120 is etched to form three channels 124A, 124B, and 124C (collectively “124”). The channels 124 terminate in through holes 126A, 126B, 126C (collectively “126”) fluidly coupled to ports through the slider 100. As best illustrated in FIG. 7, bottom surface 128 of the slider 100 includes three air bearing surfaces 130A, 130B, and 130C, each with a plurality of holes 132 fluidly coupled to the channels 124. The single pad 130C near the near field assembly 102 optimizes the tracking of the tip 110 with the waviness of the master 52. The four-pad design of FIG. 5, by contrast, averages the waviness of the master 52 across the entire lower surface of the slider 210.

The substrate 54 may be any suitable material, such as a wafer of single-crystal silicon. The photo-resist 56 is preferably a photo-resist that is generally insensitive to light with a wavelength greater than about 400 nm so that it can be handled in room light. The photo-resist is a material that changes its optical or chemical etching properties when heated by exposure to laser radiation.

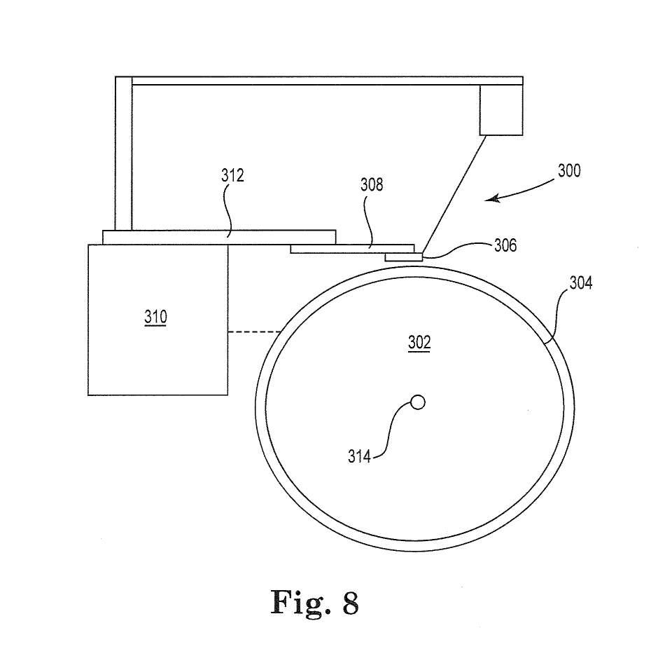

FIG. 8 is a schematic illustration of a maskless nanophotolithography system 300 with a hydrostatic gas bearing for use with non-planar substrates in accordance with an embodiment of the present invention. In the illustrated embodiment, the non-planar substrate 302 is a cylindrical roll 302 with a photo-resist layer 304.

Slider 306 is mounted on a suspension 308 with a head gimbal assembly or flexure that permits “pitch” and “roll” relative to the cylindrical roll 302, as discussed above. Support arm 312 and/or controller 310 preferably translates in the X, Y, and/or Z directions relative to the cylindrical roll 302. The cylindrical roll 302 also rotates around axis 314. A rotary actuator optionally rotates the support arm 312 along a generally radial or arcuate path. Consequently, the slider 306 can be positioned anywhere on the surface of the cylindrical roll 302.

One or more near field assemblies located on the slider 306 selectively heats the photo-mask 304 to form the desired pattern. The cylindrical roll 302 is then etched to create the desired patterns. The cylindrical roll 302 can be the final article or can be used to imprint the pattern into another article. For example, the etched cylindrical roll 302 can be a negative used to transfer the pattern to another roll, planar substrate, flexible substrate, and the like.

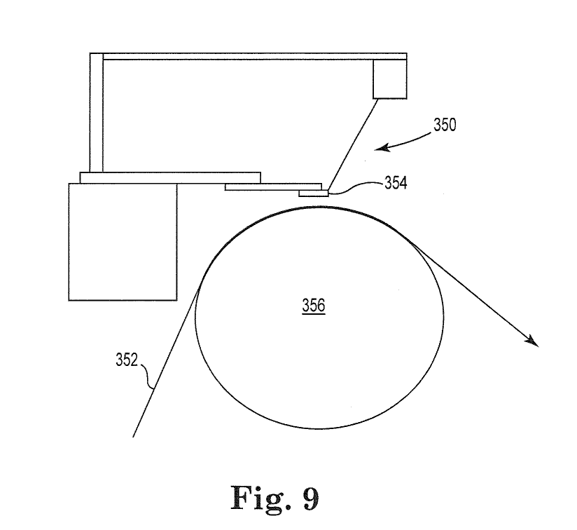

FIG. 9 is a schematic illustration of a maskless nanophotolithography system 350 with a hydrostatic gas bearing for use with a flexible substrate 352 in accordance with an embodiment of the present invention. The flexible substrate 352 can be a polymeric film, a metal foil, or a combination thereof, coated with a photo-resist layer. The flexible substrate 352 is positioned opposite slider 354 on roll 356. The desired pattern is then formed directly onto a flexible substrate 352 as discussed herein.

In one embodiment, a plurality of sliders are positioned along the length of the cylindrical roll to simultaneously form the desired pattern in the flexible cylindrical roll 302 or the flexible film 352.

Where a range of values is provided, it is understood that each intervening value, to the tenth of the unit of the lower limit unless the context clearly dictates otherwise, between the upper and lower limit of that range and any other stated or intervening value in that stated range is encompassed within the inventions. The upper and lower limits of these smaller ranges which may independently be included in the smaller ranges is also encompassed within the inventions, subject to any specifically excluded limit in the stated range. Where the stated range includes one or both of the limits, ranges excluding either both of those included limits are also included in the inventions.

Unless defined otherwise, all technical and scientific terms used herein have the same meaning as commonly understood by one of ordinary skill in the art to which these inventions belong. Although any methods and materials similar or equivalent to those described herein can also be used in the practice or testing of the present inventions, the preferred methods and materials are now described. All patents and publications mentioned herein, including those cited in the Background of the application, are hereby incorporated by reference to disclose and described the methods and/or materials in connection with which the publications are cited.

The publications discussed herein are provided solely for their disclosure prior to the filing date of the present application. Nothing herein is to be construed as an admission that the present inventions are not entitled to antedate such publication by virtue of prior invention. Further, the dates of publication provided may be different from the actual publication dates which may need to be independently confirmed.

Other embodiments of the invention are possible. Although the description above contains much specificity, these should not be construed as limiting the scope of the invention, but as merely providing illustrations of some of the presently preferred embodiments of this invention. It is also contemplated that various combinations or sub-combinations of the specific features and aspects of the embodiments may be made and still fall within the scope of the inventions. It should be understood that various features and aspects of the disclosed embodiments can be combined with or substituted for one another in order to form varying modes of the disclosed inventions. Thus, it is intended that the scope of at least some of the present inventions herein disclosed should not be limited by the particular disclosed embodiments described above.

Thus the scope of this invention should be determined by the appended claims and their legal equivalents. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims Furthermore, no element, component, or method step in the present disclosure is intended to be dedicated to the public regardless of whether the element, component, or method step is explicitly recited in the claims.

What is claimed is:

1. A photolithography system for creating a pattern of exposed regions in a photo-resist layer on substrate, the photolithography system comprising:
a head suspension assembly comprising a load beam having a flexure at a distal end, and a plurality of channels;
a covering layer extending over the channels to form gas conduits;
a slider comprising a first surface attached to the flexure and a second surface facing the substrate, the first surface of the slider including a plurality of ports fluidly coupled to the conduits, the ports extending through the slider and exiting through holes in at least one air bearing surface located on the second surface;
a near field assembly on the slider that emits radiation onto at least one region of the photo-resist in response to incident radiation, the region having a maximum dimension of less than about 100 nanometers;
a laser assembly adapted to supply the incident radiation;
a source of pressurized gas delivered to the conduits to maintain a clearance between the near field assembly and the photo-resist layer of less than about 100 nanometers; and
a controller adapted to synchronize activation of the laser assembly with the position of the substrate relative to the near field assembly.

2. The photolithography system of claim 1 comprising:
a base plate at a proximal end of the head suspension; and
a flexible conduit fluidly coupling the conduits on the head suspension to a source of pressurized gas.

3. The photolithography system of claim 1 wherein the near field assembly comprises a near field transducer located on an edge of the slider.

4. The photolithography system of claim 1 comprising an aperture structure extending from the first surface to the second surface of the slider, the aperture structure comprising a material substantially reflective to the incident radiation and an aperture having a cross-sectional size less than a wavelength of the incident radiation.

5. The photolithography system of claim 1 wherein the substrate is one or more of flexible, rigid, planar, non-planar, or cylindrical.

6. The photolithography system of claim 1 wherein the laser assembly supplies radiation at a first wavelength and the near field assembly emits radiation at a second shorter wavelength in response to incident radiation.

7. The photolithography system of claim 1 wherein the region of radiation emitted onto the photo-resist has a maximum dimension of less than about 80 nanometers.

8. The photolithography system of claim 1 wherein the region of radiation emitted onto the photo-resist has a maximum dimension of less than about 60 nanometers.

9. The photolithography system of claim 1 wherein the pattern comprises features having a size less than about a wavelength of the incident radiation.

10. The photolithography system of claim 1 wherein the pattern comprises features having a size less than about 50% of a wavelength of the incident radiation.

11. The photolithography system of claim 1 wherein the pattern comprises features having a size less than about 20% of a wavelength of the incident radiation.

12. The photolithography system of claim 1 comprising a sensor monitoring the clearance between the near field assembly and the photo-resist layer.

13. The photolithography system of claim 1 wherein the clearance between the near field assembly and the photo-resist layer of less than about 50 nanometers.

14. The photolithography system of claim 1 wherein the clearance between the near field assembly and the photo-resist layer of less than about 20 nanometers.

15. A plasmonic head for creating a pattern of exposed regions in a photo-resist layer on substrate, the plasmonic head comprising:
a head suspension assembly comprising a load beam having a flexure at a distal end, and a plurality of channels;
a covering layer extending over the channels to form gas conduits;
a slider comprising a first surface attached to the flexure and a second surface facing the substrate, the first surface of the slider including a plurality of ports fluidly coupled to the gas conduits, the ports extending through the slider and exiting through holes in at least one air bearing surface located on the second surface, the ports adapted to emit a gas to maintain a clearance between the second surface and the photo-resist layer of less than about 100 nanometers; and
a near field assembly on the slider that emits radiation onto a region of the photo-resist in response to incident radiation with a maximum dimension of less than about 100 nanometers.

16. A method for forming a pattern in photo-resist layer on a substrate using a photolithography system, the method comprising the step of:
delivering a pressurized gas through gas conduits in a head suspension to ports on a slider;
ejecting the pressurized gas from the ports in the slider to create a hydrostatic gas bearing with a clearance between a near field assembly and a photo-resist layer of less than about 100 nanometers;
directing incident radiation from a laser assembly to the near field assembly;
emitting a region of radiation from the near field assembly onto the photo-resist in response to the incident radiation with a maximum dimension of less than about 100 nanometers; and
synchronizing activation of the laser assembly with a position the substrate relative to the near field assembly to form the pattern.
